(19) United States
(12) Patent Application Publication
(10) Pub. No.: US 2025/0268004 A1
(43) Pub. Date: Aug. 21, 2025

(54) DISPLAY DEVICE , METHOD OF MANUFACTURING THE SAME, AND ELECTRONIC DEVICE INCLUDING THE SAME

(71) Applicant: SAMSUNG DISPLAY CO., LTD., YONGIN-SI (KR)

(72) Inventors: YEONGHO KIM, Yongin-si (KR); SIEUN CHEON, Yongin-si (KR)

(21) Appl. No.: 18/989,567

(22) Filed: Dec. 20, 2024

(30) Foreign Application Priority Data
Feb. 20, 2024 (KR) 10-2024-0024636

(51) Int. Cl. H10H 29/49; H10H 29/01

(52) U.S. Cl. CPC H10H 29/49; H10H 29/012

(57) ABSTRACT

A display device includes a display panel including a first area in which a pixel is disposed, a second area extending in a first direction, a third area spaced apart from the first area by the second area in a second direction perpendicular to the first direction, and a first cutting line penetrating at least a portion of the display panel and extending from an intersection point formed by a first straight portion included in the first area and a second straight portion included in the second area.

### CROSS-REFERENCE TO RELATED APPLICATION(S)

This application claims priority under 35 U.S.C. § 119 to Korean Patent Application No. 10-2024-0024636, filed on Feb. 20, 2024, in the Korean Intellectual Property Office, the content of which is hereby incorporated by reference for all purposes as if fully set forth herein.

### BACKGROUND

### 1. Technical Field

Embodiments relate to a display device and a method of manufacturing the same. More particularly, embodiments relate to a display device including a cutting line in a display panel and the method of manufacturing the same.

### 2. Discussion of Related Art

A display device is a device configured to display images that may be perceived as visual information by a user. The display device may include pixels and a driving chip. The driving chip may provide a driving signal to the pixels and the pixels may emit light, which forms an image. The pixels may be disposed in an area of the display device that displays an image, and the driving chip may be disposed in an area of the display device that does not display an image.

In some display devices an area that does not display an image may be reduced by locating the driving chip below the pixels, and connecting the driving chip to the pixels may a flexible connection that may be bent. In some cases, stress may be concentrated around a portion where the flexible connection is bent.

### SUMMARY

Embodiments provide a display device with an improved durability.

Embodiments provide a method of manufacturing the display device including a cutting line in a display panel.

A display device according to an embodiment may include display panel including a first area in which a pixel is disposed, a second area extending in a first direction, a third area spaced apart from the first area by the second area in a second direction perpendicular to the first direction, and a first cutting line penetrating at least a portion of the display panel and extending from an intersection point formed by a first straight portion included in the first area and a second straight portion included in the second area.

In an embodiment, the display device may further include a fan-out line electrically connected to the pixel and extending across a boundary of the first area and the second area, and the first cutting line may be spaced apart from the fan-out line.

In an embodiment, the first cutting line may extend in the first direction from the intersection point.

In an embodiment, the first cutting line may extend in a direction opposite to the second direction from the intersection point.

In an embodiment, the first cutting line may extend in a third direction, which intersects with both of the first direction and the second direction in a plan view.

In an embodiment, a second cutting line penetrates at least a portion of the display panel and extends from the intersection point.

In an embodiment, the display panel may further include fan-out lines which are electrically connected to the pixel, and extend across a boundary of the first area and the second area, and the second cutting line is spaced apart from the fan-out lines.

In an embodiment, the first cutting line and the second cutting line may intersect perpendicularly at the intersection point.

In an embodiment, a length of the first cutting line and a length of the second cutting line may be different from each other.

In an embodiment, the display device may further include a bending protective layer overlapping at least a portion of each of the first area, the second area, and the third area, wherein the second area is bent along a bending axis extending in a first direction.

In an embodiment, the first cutting line further may penetrate at least a portion of the bending protective layer.

In an embodiment, the display panel may define a recess portion by the first straight portion and the second straight portion.

In an embodiment, the recess portion has a L shape in a plan view.

In an embodiment, wherein the first straight portion and the second straight portion may intersect perpendicularly.

A method of manufacturing a display device according to an embodiment may include forming a bending protective layer on a display panel including a first area in which a pixel is disposed, a second area extending in a first direction, and a third area spaced apart from the first area by the second area in a second direction perpendicular to the first direction, forming a first straight portion included in the display panel by irradiating a light in the first area along the first direction, forming a second straight portion included in the display panel by irradiating a light in the second area along the second direction, and forming a cutting line in the display panel by irradiating a light from an intersection point where the first straight portion and the second straight portion intersect.

In an embodiment, a recess portion may be formed that is defined by the first straight portion and the second straight portion by removing a portion of each of the display panel and the bending protective layer.

In an embodiment, the cutting line may be formed after the recess portion is formed.

In an embodiment, the display panel may be provided including a fan-out line electrically connected to the pixel and extend across a boundary of the first area and the second area, and in the forming of the cutting line, the light may be irradiated from the intersection point toward the fan-out line for a distance less than a distance from the intersection point to the fan-out line.

In an embodiment, in the forming of the cutting line, the light may be irradiated along the first direction from the intersection point.

In an embodiment, in the forming of the cutting line, the light may be irradiated along a direction opposite to the second direction from the intersection point.

An electronic device according to an embodiment may include a processor outputting an image data signal and an input control signal and a display device driving based on the image data signal and the input control signal. The display device may include display panel including a first area in which a pixel is disposed, a second area extending in a first direction, a third area spaced apart from the first area by the second area in a second direction perpendicular to the first direction, and a first cutting line penetrating at least a portion of the display panel and extending from an intersection point formed by a first straight portion included in the first area and a second straight portion included in the second area.

In a display device according to embodiments of the present disclosure, a display panel may include a first straight portion, a second straight portion, and a cutting line, which extends along a direction from an intersection point where the first straight portion and the second straight portion intersect and penetrates at least a portion of the display panel. The first straight portion and the second straight portion may intersect each other perpendicularly. Accordingly, when the display panel is bent in a bending area, a pressing phenomenon in which components of the display device disposed in a pad area may be recessed in a thickness direction may be inhibited or prevented.

In addition, as the first straight portion and the second straight portion intersect each other perpendicularly, the cutting line may reduce a stress concentrated at the intersection point. Accordingly, a generation of cracks in the display panel may be reduced, and a durability of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of present disclosure.

FIG. 2 is a plan view illustrating a display panel of FIG. 1.

FIG. 3 is a cross-sectional view illustrating an unfolded state of a cross-section taken along line I-I′ of FIG. 1.

FIG. 4 is a cross-sectional view illustrating an bent state of a cross-section taken along line I-I′ of FIG. 1.

FIG. 5 is a cross-sectional view illustrating a cross-section taken along line II-II′ of FIG. 1.

FIG. 6 is a plan view illustrating an example of an enlarged plane of an area A of FIG. 1.

FIG. 7, FIG. 8, FIG. 9, and FIG. 10 are views illustrating a method of manufacturing the display device of FIG. 1.

FIG. 11 is a plan view illustrating another example of an enlarged plane of an area A of FIG. 1.

FIG. 12 is a plan view illustrating still another example of an enlarged plane of an area A of FIG. 1.

FIG. 13 is a plan view illustrating still another example of an enlarged plane of an area A of FIG. 1.

FIG. 14 is a block diagram of an electronic device according to an embodiment of the present disclosure.

FIG. 15 is a schematic diagram of the electronic device according to various embodiments of the present disclosure.

### DETAILED DESCRIPTION

Hereinafter, display devices in accordance with embodiments will be described in more detail with reference to the accompanying drawings. In the drawings, same reference numerals are used for the same components, and redundant descriptions of the same components may be omitted. Further, the thicknesses, the ratios, and the dimensions of the components depicted in the drawings may be exaggerated for effective description of the technical contents.

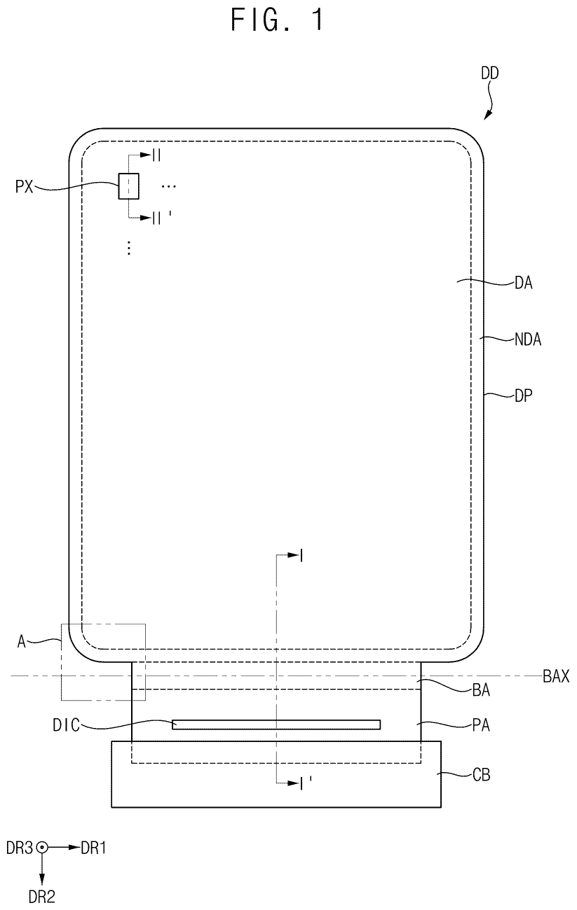

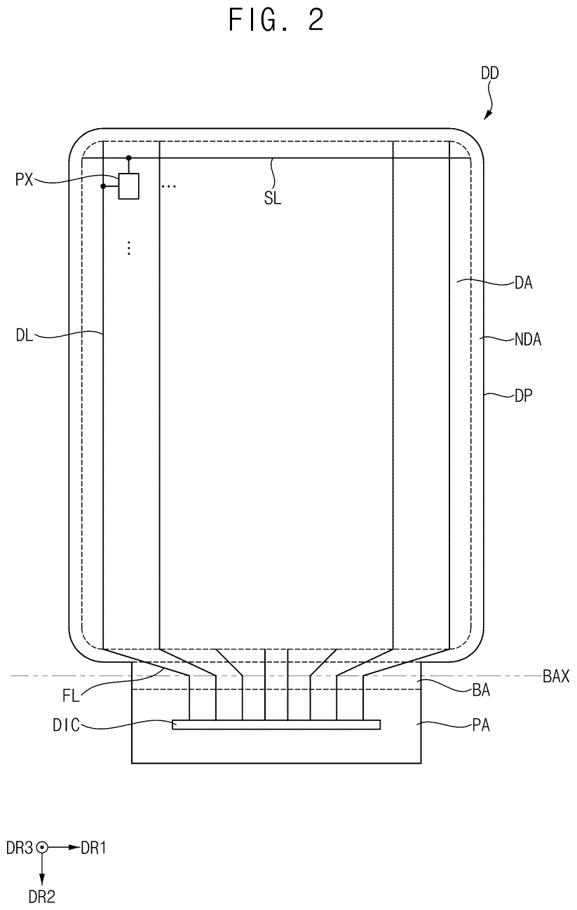

FIG. 1 is a plan view illustrating a display device according to an embodiment of present disclosure. FIG. 2 is a plan view illustrating a display panel of FIG. 1.

Referring to FIG. 1 and FIG. 2, the display device DD according to an embodiment of the present disclosure may include a display panel DP, a driving chip DIC, and a circuit board CB. The display panel DP may include a pixel PX, scan lines SL, data lines DL, and fan-out lines FL.

The display panel DP may include a display area DA, a non-display area NDA, a bending area BA, and a pad area PA. As the display device DD includes the display panel DP, the display device DD may include the display area DA, the non-display area NDA, the bending area BA, and the pad area PA. The display area DA may be an area in which an image may be generated. The non-display area NDA, the bending area BA, and the pad area PA may be areas which do not generate an image.

In this specification, a plane may be defined by a first direction DR1 and a second direction DR2 intersecting with the first direction DR1. For example, the first direction DR1 and the second direction DR2 intersect perpendicularly. In addition, a third direction DR3 may intersect perpendicularly with the plane defined by the first direction DR1 and the second direction DR2.

The pixel PX may be disposed in the display area DA. A plurality of pixels PX, including the pixel PX, may be disposed in the display area DA. An image may be generated by the plurality of pixels PX, wherein the plurality of pixels PX emit light.

The plurality of pixels PX may be arranged in the first direction DR1 and the second direction DR2. In addition, the pixel PX may include a plurality of sub-pixels that emit light of different colors. For example, the sub-pixels may include a red sub-pixel that emits red light, a green sub-pixel that emits green light, and a blue sub-pixel that emits blue light.

The data lines DL and the scan lines SL may be disposed in the display area DA. The data lines DL and the scan lines SL may cross each other. The data lines DL may extend in the second direction DR2. The plurality of data lines DL may be arranged in the first direction DR1. In addition, the scan lines SL may extend in the first direction DR1. The plurality of scan lines SL may be arranged in the second direction DR2. Each pixel PX may be electrically connected to a data line DL and a scan line SL.

The non-display area NDA may be adjacent to the display area DA. For example, the non-display area NDA may surround at least a portion of the display area DA. Components for driving the pixel PX may be disposed in the non-display area NDA. For example, the components may include a scan driver and an light-emitting driver. The components for driving the pixel PX may transmit signals such as a scan signal and an light-emitting control signal to the pixel PX through the scan lines SL. The pixel PX may emit light based on the signals.

The bending area BA may be adjacent to the non-display area NDA. For example, the bending area BA may be adjacent to a side of the non-display area NDA in the second direction DR2. The bending area BA may be bent along a bending axis BAX. For example, the bending axis BAX may extend in the first direction DR1. The bending axis BAX may be a central axis in the bending area BA. The bending axis BAX may be an axis of a bend of the display panel DP in the bending area BA.

The pad area PA may be adjacent to the bending area BA. For example, the pad area PA may be adjacent to a side of the bending area BA in the second direction DR2. The pad area PA may be spaced apart from the display area DA and the non-display area NDA in the second direction DR2. For example, the pad area PA may be spaced apart from the non-display area NDA in the second direction DR2. The pad area PA may be separated from the non-display area NDA by the bending area BA.

The driving chip DIC may be disposed in the pad area PA. The driving chip DIC may be disposed on the display panel DP. The driving chip DIC may be electrically connected to the pixel PX. The driving chip DIC may generate a data signal to drive the pixel PX. The pixel PX may emit light based on the data signal. The driving chip DIC may include a data driver for generating the data signal.

The fan-out lines FL may be disposed in the non-display area NDA, the bending area BA, and the pad area PA. The fan-out lines FL may extend between the non-display area NDA and the pad area PA. For example, at least some of the fan-out lines FL may include portions that are disposed at angles to the second direction DR2 in the bending area BA and the non-display area NDA. However, the present disclosure may not be limited to this, and at least some of the fan-out lines FL may include portions that are disposed at angles to the second direction DR2 in the pad area PA. The fan-out lines FL may be electrically connected to the driving chip DIC and the data lines DL. The fan-out lines FL may transmit the data signal transmitted from the driving chip DIC to each of the data lines DL. Accordingly, the data signals transmitted to each of the data lines DL may be transmitted to the pixel PX.

The circuit board CB may be adjacent to a portion of the display panel DP located in the pad area PA. At least a portion of the circuit board CB may overlap with at least a portion of the pad area PA. At least a portion of the circuit board CB may be disposed on the display panel DP in the pad area PA. The circuit board CB may supply a driving signal to the display panel DP. The circuit board CB may include a timing controller that controls the operation of the display panel DP and a power voltage generator that provides a power supply voltage to the display panel DP.

In this specification, the display area DA and the non-display area NDA may be referred to as a first area. The bending area BA may be referred to as a second area. The pad area PA may be referred to as a third area.

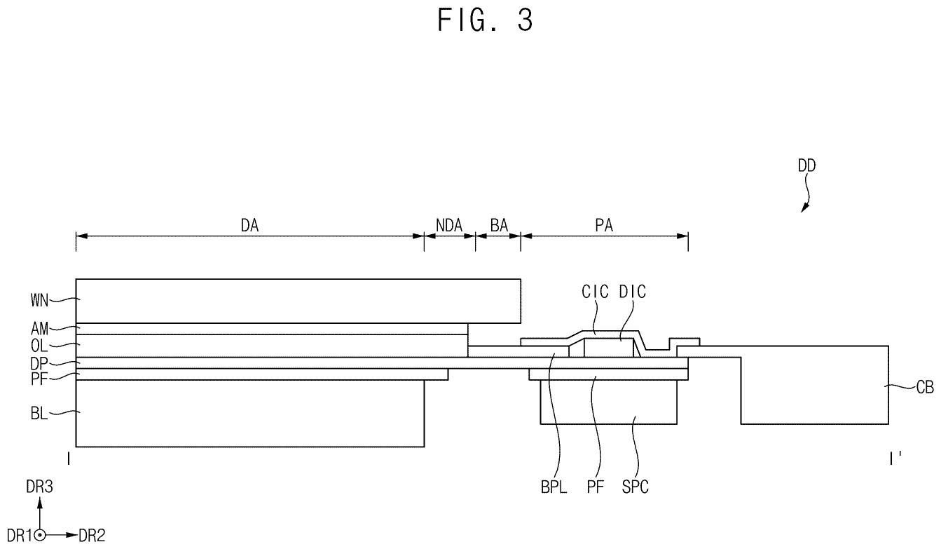

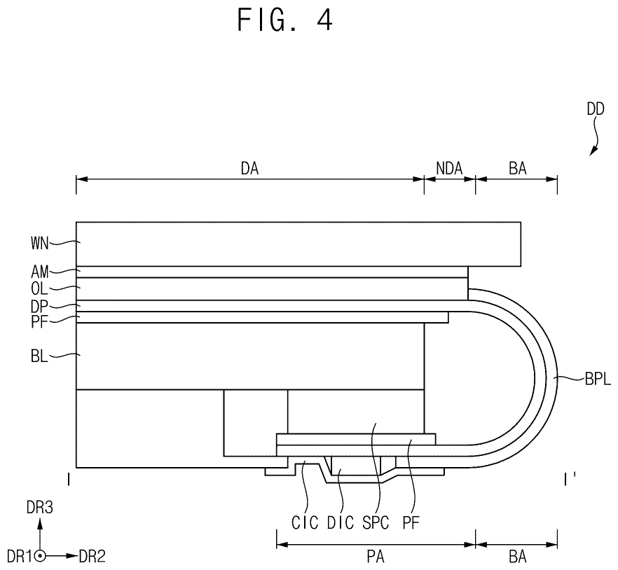

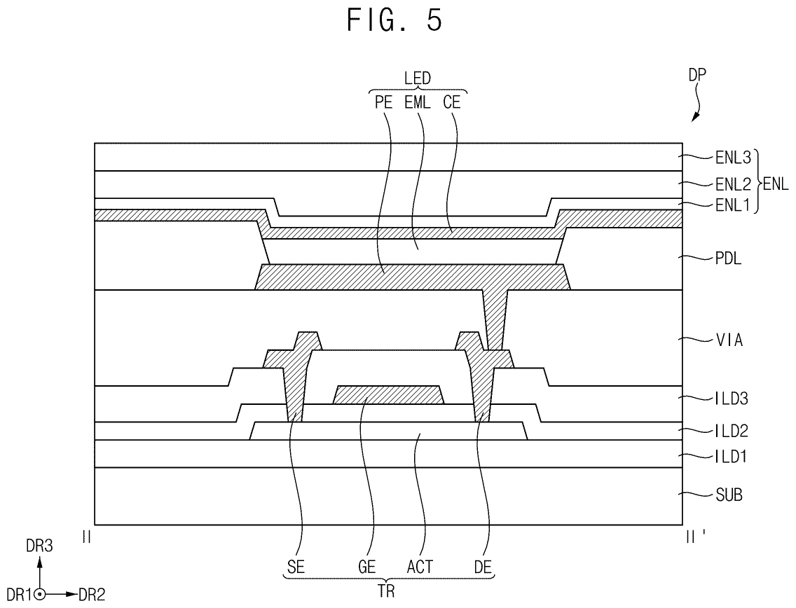

FIG. 3 is a cross-sectional view illustrating an unfolded state of a cross-section taken along line I-I′ of FIG. 1. FIG. 4 is a cross-sectional view illustrating an bent state of a cross-section taken along line I-I′ of FIG. 1. FIG. 5 is a cross-sectional view illustrating a cross-section taken along line II-II′ of FIG. 1.

Referring to FIG. 3, FIG. 4, and FIG. 5, the display device DD may include the display panel DP, a protective film PF, a lower support layer BL, a bending protective layer BPL, the driving chip DIC, a cover member CIC, the circuit board CB, a spacer SPC, an optical layer OL, an adhesive member AM, and a window layer WN.

The display panel DP may be disposed in the display area DA, the non-display area NDA, the bending area BA, and the pad area PA. The display panel DP may have a first side and a second side. The first side may be an upper side and the second side may be a lower side as illustrated in FIG. 3. The display panel DP may be bent along the bending axis BAX of FIG. 1 in the bending area BA. Accordingly, the first side of the display panel DP may face the bending protective layer BPL and outside of the display device DD, and the second side of the display panel DP opposite to the first side may face inside of the display device DD (see FIG. 4). As the display panel DP is bent, the pad area PA may overlap at least a portion of the non-display area NDA and a portion of the display area DA in a plane perpendicular to the third direction DR3.

The display panel DP may include a substrate SUB, a first insulating layer ILD1, a second insulating layer ILD2, a third insulating layer ILD3, a transistor TR, a via insulating layer VIA, a pixel defining layer PDL, a light-emitting element LED, and an encapsulation layer ENL. The transistor TR may include an active layer ACT, a gate electrode GE, a source electrode SE, and a drain electrode DE. The light-emitting element LED may include a pixel electrode PE, an light-emitting layer EML, and a common electrode CE. The encapsulation layer ENL may include a first encapsulation layer ENL1, a second encapsulation layer ENL2, and a third encapsulation layer ENL3.

The substrate SUB may be a transparent insulating substrate. For example, the substrate SUB may include a glass, a quartz, or a plastic. These materials may be used alone or in combination with each other.

The first insulating layer ILD1 may be disposed on the substrate SUB. The first insulating layer ILD1 may inhibit or prevent impurities from diffusing from the substrate SUB to the active layer ACT.

The first insulating layer ILD1 may include an inorganic insulating material. The inorganic insulating material may include a silicon nitride SiNₓ, a silicon oxide SiOₓ, or a silicon oxynitride SiOₓN_{y}. These materials may be used alone or in combination with each other.

The active layer ACT may be disposed on the first insulating layer ILD1. The active layer ACT may include an amorphous silicon, a polycrystalline silicon, or an oxide semiconductor. The active layer ACT may include a source area and a drain area doped with impurities, and a channel area disposed between the source area and the drain area.

The second insulating layer ILD2 may be disposed on the first insulating layer ILD1. The second insulating layer ILD2 may cover the active layer ACT disposed on the first insulating layer ILD1. For example, the second insulating layer ILD2 may have a substantially uniform thickness along the profile of the active layer ACT. For example, the second insulating layer ILD2 may be a conformal layer. Alternatively, the second insulating layer ILD2 may have a thickness to sufficiently cover the active layer ACT and may have a substantially flat upper surface without creating a step around the active layer ACT.

The second insulating layer ILD2 may include an inorganic insulating material. The inorganic insulating material may include a silicon nitride SiNₓ, a silicon oxide SiOₓ, or a silicon oxynitride SiOₓN_{y}. These materials may be used alone or in combination with each other.

The gate electrode GE may be disposed on the second insulating layer ILD2. The gate electrode GE may overlap the channel area of the active layer ACT. The gate electrode GE may include a metal, an alloy, a conductive metal oxide, a conductive metal nitride, or a transparent conductive material.

The third insulating layer ILD3 may be disposed on the second insulating layer ILD2. The third insulating layer ILD3 may cover the gate electrode GE disposed on the second insulating layer ILD2. For example, the third insulating layer ILD3 may have a substantially uniform thickness along the profile of the gate electrode GE. For example, the third insulating layer ILD3 may be a conformal layer. Alternatively, the third insulating layer ILD3 may have a thickness to sufficiently cover the gate electrode GE and may have a substantially flat upper surface without creating a step around the gate electrode GE.

The source electrode SE and the drain electrode DE may be disposed on the third insulating layer ILD3. The source electrode SE may contact the active layer ACT through a first contact hole penetrating the second insulating layer ILD2 and the third insulating layer ILD3. The drain electrode DE may contact the active layer ACT through a second contact hole penetrating the second insulating layer ILD2 and the third insulating layer ILD3. The source electrode SE may overlap the source area of the active layer ACT. The drain electrode DE may overlap the drain area of the active layer ACT. Each of the source electrode SE and the drain electrode DE may include a metal, an alloy, a conductive metal oxide, a conductive metal nitride, or a transparent conductive material. The active layer ACT, the gate electrode GE, the source electrode SE, and the drain electrode DE may form the transistor TR.

The via insulating layer VIA may be disposed on the third insulating layer ILD3. The via insulating layer VIA may be disposed on the source electrode SE and the drain electrode DE disposed on the third insulating layer ILD3. The via insulating layer VIA may have a substantially flat upper surface. The via insulating layer VIA may include an organic insulating material such as a polyimide (PI). In an embodiment, an opening in the via insulating layer VIA may expose a portion of the upper surface of the drain electrode DE. In another embodiment, an opening in the via insulating layer VIA may expose a portion of the upper surface of the source electrode SE.

The pixel defining layer PDL may be disposed on the via insulating layer VIA. The pixel defining layer PDL may cover a portion of the pixel electrode PE. In addition, the pixel defining layer PDL may include an opening that exposes at least a portion of the pixel electrode PE. For example, the opening of the pixel defining layer PDL may expose a central portion of the pixel electrode PE. The pixel defining layer PDL may be disposed on edge portions of the pixel electrode PE. The pixel defining layer PDL may include a same material as the via insulating layer VIA. For example, the pixel defining layer PDL may include an organic insulating material such as a polyimide (PI).

The pixel electrode PE may be disposed on the via insulating layer VIA. In an embodiment, the pixel electrode PE may contact the drain electrode DE through the opening in the via insulating layer VIA. In another embodiment, the pixel electrode PE may contact the source electrode SE through the opening in the via insulating layer VIA. The pixel electrode PE may include a metal, an alloy, a conductive metal oxide, a conductive metal nitride, or a transparent conductive material. These materials may be used alone or in combination with each other. For example, the pixel electrode PE may include a silver (Ag) and an indium tin oxide (ITO).

The light-emitting layer EML may be disposed on the pixel defining layer PDL. The light-emitting layer EML may be disposed on the pixel electrode PE exposed by the opening of the pixel defining layer PDL. For example, the light-emitting layer EML may be disposed on sidewalls of the pixel defining layer PDL. The light-emitting layer EML may include an organic light-emitting material. The organic light-emitting material may include a low molecular weight organic compound or a high molecular weight organic compound. However, the present disclosure may not be limited to this, and the light-emitting layer EML may include materials such as quantum dots.

The common electrode CE may be disposed on the light-emitting layer EML. The common electrode CE may include a metal, an alloy, a conductive metal oxide, a conductive metal nitride, or a transparent conductive material. For example, the common electrode CE may include an aluminum (Al), a platinum (Pt), a silver (Ag), a magnesium (Mg), a gold (Au), a chromium (Cr), a tungsten (W), or a titanium (Ti). These materials may be used alone or in combination with each other. The pixel electrode PE, the light-emitting layer EML, and the common electrode CE may form a light-emitting element LED.

The first encapsulation layer ENL1 may be disposed on the common electrode CE. The first encapsulation layer ENL1 may cover the light-emitting element LED. The first encapsulation layer ENL1 may have a substantially uniform thickness along the profile of the common electrode CE. For example, the first encapsulation layer ENL1 may be a conformal layer.

The second encapsulation layer ENL2 may be disposed on the first encapsulation layer ENL1. The second encapsulation layer ENL2 may not create a step around the first encapsulation layer ENL1 and may have a substantially flat upper surface.

The third encapsulation layer ENL3 may be disposed on the second encapsulation layer ENL2. The third encapsulation layer ENL3 may have a substantially uniform thickness and a substantially flat upper surface. The first to third encapsulation layers ENL1, ENL2, and ENL3 may seal the display area DA and protect the light-emitting element LED from external impurities.

The protective film PF may be disposed on the lower side of the display panel DP. For example, the protective film PF may be disposed in the display area DA, the non-display area NDA, and the pad area PA on the lower side of the display panel DP. In other words, the protective film PF may not be disposed in the bending area BA. For example, the protective film PF may expose the lower side of the display panel DP in the bending area BA.

As illustrated in FIG. 3, when the display panel DP is unfolded in the bending area BA, the protective film PF disposed in the display area DA and the non-display area NDA may be spaced apart from the protective film PF disposed in the pad area PA in the second direction DR2. In addition, as illustrated in FIG. 4, when the display panel DP is bent in the bending area BA, the protective film PF disposed in the display area DA and the non-display area NDA may be disposed opposite to the protective film PF disposed in the pad area PA in the third direction DR3.

The protective film PF may include a polymer material. For example, the polymer material may include a polyimide (PI), a polyethylene terephthalate (PET), a polycarbonate (PC), a polysulfone (PSF), or a polymethyl methacrylate (PMMA). These materials may be used alone or in combination with each other.

The lower support layer BL may be disposed under the protective film PF. For example, the lower support layer BL may be disposed under the protective film PF in the display area DA. However, embodiments of the present disclosure may not be limited to this, and the lower support layer BL may overlap at least a portion of the display area DA and the non-display area NDA. However, the lower support layer BL may not be disposed in the bending area BA and the pad area PA under the display panel DP (see FIG. 3).

The lower support layer BL may support the display panel DP. The lower support layer BL may include a metal, a glass, or a fiber reinforced plastic (FRP).

The bending protective layer BPL may be disposed on the display panel DP. The bending protective layer BPL may be disposed on the upper side of the display panel DP. For example, the bending protective layer BPL may be disposed in the bending area BA on the display panel DP. Specifically, the bending protective layer BPL may be disposed on the display panel DP throughout the bending area BA and in at least a portion of the pad area PA. However, an arrangement of the bending protective layer BPL according to an embodiment of the present disclosure may not be limited to this, and the bending protective layer BPL may be disposed in a portion of the bending area BA.

As the display panel DP is bent in the bending area BA, the bending protective layer BPL may also be bent along the bending axis BAX of FIG. 1 in the bending area BA. The bending protective layer BPL may protect a portion of the display panel DP where the display panel DP is bent. A first side of the bent bending protective layer BPL may face the outside of the display device DD, and a second side of the bending protective layer BPL opposite to the first side may face the display panel DP and the inside of the display device DD. A thickness of the bending protective layer BPL may be less than a thickness of the optical layer OL.

The bending protective layer BPL may include a photocurable resin or a thermosetting resin. For example, the bending protective layer BPL may include an epoxy resin, an amino resin, a phenol resin, an urea resin, a melamine resin, an unsaturated polyester resin, a polyurethane resin, or a polyimide resin. These materials may be used alone or in combination with each other.

As described herein, the driving chip DIC may be disposed on the display panel. For example, the driving chip DIC may be disposed on the display panel in the pad area PA. The driving chip DIC may be spaced apart from the bending protective layer BPL in the pad area PA in the second direction DR2.

The driving chip DIC may have a chip on plastic (COP) structure or a chip on glass (COG) structure. For example, the driving chip DIC may be disposed directly on the display panel DP. However, a structure of the driving chip DIC according to embodiments of the present disclosure may not be limited to this, and the driving chip DIC may have a chip on film (COF) structure, wherein the driving chip DIC may be disposed directly on a flexible film. In this case, the circuit board CB may be electrically connected to the flexible film.

The cover member CIC may be disposed on the driving chip DIC. In an embodiment, the cover member CIC may be disposed on a portion of the circuit board CB and a portion of the bending protective layer BPL. Specifically, the cover member CIC may cover the driving chip DIC while contacting a portion of each of the circuit board CB and the bending protective layer BPL. Accordingly, the cover member CIC may protect the driving chip DIC from, for example, external shocks or impurities.

Alternatively, the cover member CIC may be disposed on a portion of each of the circuit board CB and the display panel DP. For example, the bending protective layer BPL may be spaced apart from the cover member CIC, and the cover member CIC may contact a portion of the display panel DP that is not covered by the bending protective layer BPL in the pad area PA.

In an embodiment, the cover member CIC may be a cover tape. For example, the cover tape may include synthetic resin such as polyethylene terephthalate (PET).

The circuit board CB may be disposed on the display panel DP. For example, when the display panel DP is unfolded, the circuit board CB may be disposed on the upper side of the display panel DP in the pad area PA. When the display panel DP is bent, a first side of the circuit board CB may face a lower portion (e.g., the third direction DR3) of the display device DD. In addition, when the display panel DP is bent, a portion of a second side of the circuit board CB opposite to the one side may contact the lower support layer BL.

The spacer SPC may be disposed below the protective film PF. The spacer SPC may be disposed below the protective film PF overlapping the pad area PA. The spacer SPC may contact a lower side of the protective film PF overlapping the pad area PA. Accordingly, when the display panel DP is bent, the spacer SPC may be disposed in a space between the lower support layer BL and the display panel DP and at least a portion of the second side of the circuit board CB may be fixed to the lower support layer BL.

The spacer SPC may include an organic insulating material. In an embodiment, the spacer SPC may include a polyethylene terephthalate, a polypropylene (PP), a polycarbonate (PC), a polystyrene (PS), or a polyethylene (PE). These materials may be used alone or in combination with each other.

The optical layer OL may be disposed on the display panel DP. The optical layer OL may perform an optical function for controlling light. In an embodiment, the optical layer OL may be a polarizing layer. The optical layer OL may be disposed on the display panel DP in the display area DA and the non-display area NDA. The optical layer OL may polarize light incident on the display panel DP from the outside. The optical layer OL may have a stretching direction (or reference axis), which may be disposed in a direction. The stretching direction of the optical layer OL may be an absorption axis, and a direction perpendicular to the stretching direction may be a transmission axis. However, the optical layer OL according to embodiments of the present disclosure may not be limited to a polarizing layer and may be various types of functional layers that perform optical functions. For example, the optical layer OL may include a color filter.

The window layer WN may be disposed on the optical layer OL. The window layer WN may be disposed on the optical layer OL in the display area DA. The window layer WN may be disposed on the optical layer OL in non-display area NDA. The window layer WN may be disposed in bending area BA. For example, the window layer WN may be disposed above the bending protective layer BPL in bending area BA. When the display panel DP and the bending protective layer BPL are bent, the window layer WN may overlap at least a portion of the display panel DP and the bending protective layer BPL in bending area BA. Accordingly, the window layer WN may protect the optical layer OL, bending protective layer BPL, and display panel DP. The window layer WN may include a tempered glass, a reinforced plastic, and the like. The window layer WN may be formed as a single layer or may have a structure in which a plurality of functional layers are stacked.

The adhesive member AM may be disposed between the optical layer OL and the window layer WN. For example, the adhesive member AM may bond the optical layer OL and the window layer WN to each other. The adhesive member AM may be disposed in the display area DA and the non-display area NDA. The adhesive member AM may include an adhesive material. For example, the adhesive material may include an optical clear adhesive (OCA), a pressure sensitive adhesive (PSA), or an optical clear resin (OCR). These materials may be used alone or in combination with each other.

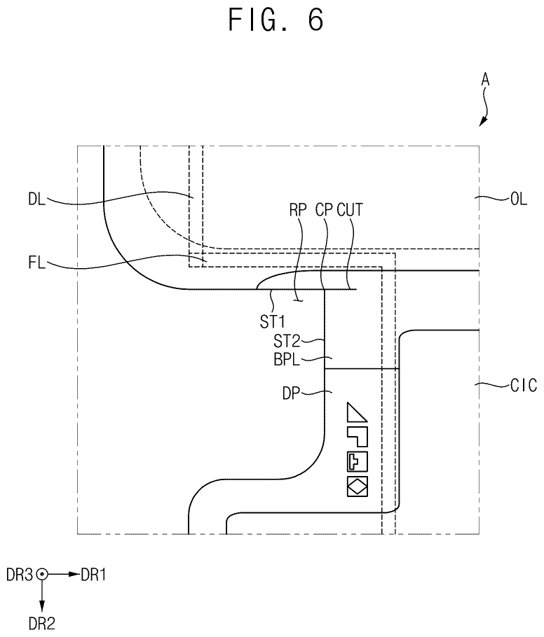

FIG. 6 is a plan view illustrating an example of an enlarged plane of an area A of FIG. 1.

Referring to FIG. 6, the display panel DP may include a first straight portion ST1 and a second straight portion ST2. The first straight portion ST1 may be a portion of an edge of the display panel DP located in the non-display area NDA of FIG. 1. The first straight portion ST1 may be a substantially straight line parallel to the first direction DR1. The second straight portion ST2 may be located in the bending area BA of FIG. 1. The second straight portion ST2 may be a substantially straight line parallel to the second direction DR2. The first and second straight portions ST1 and ST2 may be formed by simultaneously cutting a laminated structure of the display panel DP and the bending protective layer BPL. The bending protective layer BPL may include the first and second straight portions ST1 and ST2. In an embodiment, the first straight portion ST1 and the second straight portion ST2 may intersect each other perpendicularly.

A recessed portion RP may be defined in the display panel DP by the first straight portion ST1 and the second straight portion ST2. The recessed portion RP may be an area having a shape in which the display panel DP is recessed by the first straight portion ST1 and the second straight portion ST2. In an embodiment, the recessed portion RP may have a L-shape. FIG. 6 illustrates an edge portion located in a direction opposite to the first direction DR1 of the display panel DP. The edge portion located in the first direction DR1 of the display panel DP may also have shape corresponding to the first straight portion ST1 and the second straight portion ST2.

An intersection point CP, formed by the first straight portion ST1 and the second straight portion ST2 intersecting each other, may be defined. Specifically, the first straight portion ST1 may extend in the first direction DR1, and the second straight portion ST2 may extend in a direction opposite to the second direction DR2 to intersect at the intersection point CP.

A cutting line CUT may extend in a direction from the intersection point CP and may be defined in the display panel DP. In an embodiment, the cutting line CUT may extend from the intersection point CP in the first direction DR1. However, the present disclosure may not be limited to this, and the cutting line CUT may extend in another direction that intersects both the first direction DR1 and the second direction DR2 from the intersection point CP toward an inside of the display panel DP, in a plan view.

The cutting line CUT may penetrate the display panel DP. In addition, the cutting line CUT may further penetrate the bending protective layer BPL. In other words, the cutting line CUT may penetrate both the display panel DP and the bending protective layer BPL.

The cutting line CUT may be spaced apart from the fan-out lines FL that extend through an boundary between the non-display area NDA and the bending area BA of FIG. 1. In other words, the cutting line CUT may extend in a direction from the intersection point CP and may not cross the fan-out lines FL. Accordingly, the cutting line CUT may be spaced apart from a fan-out line closest to the intersection point CP among the fan-out lines FL. Accordingly, the cutting line CUT may not affect the fan-out lines FL. That is, the fan-out lines FL may not be damaged by the cutting line CUT.

In an embodiment, a length of the cutting line CUT may be less than a distance between the intersection point CP and the fan-out line. Specifically, the length of the cutting line CUT may extend in the first direction DR1 and may have a value that is less than the distance between the intersection point CP and the fan-out line.

In this specification, the cutting line CUT may be referred to as a first cutting line.

As described herein, the display device (e.g., the display device DD of FIG. 1) according to an embodiment of the present disclosure may include the display panel DP. The display panel DP may include the first straight portion ST1, the second straight portion ST2, and the cutting line CUT that extends from the intersection point CP of the first straight portion ST1 and the second straight portion ST2. The cutting line CUT may penetrate a portion of the display panel DP. The first straight portion ST1 and the second straight portion ST2 may intersect each other perpendicularly. Accordingly, when the display panel DP is bent in the bending area BA of FIG. 1, a pressing phenomenon where components of the display device DD disposed in the pad area PA of FIG. 1 may be recessed in a thickness direction (e.g., the third direction DR3 of FIG. 1), may be inhibited or prevented.

In addition, the cutting line CUT may reduce a stress concentrated at the intersection point CP in an embodiment in which the first straight portion ST1 and the second straight portion ST2 intersect each other perpendicularly. In addition, the cutting line CUT may reduce a probability that a crack may be generated in the display device DD, and a durability of the display device DD may be improved.

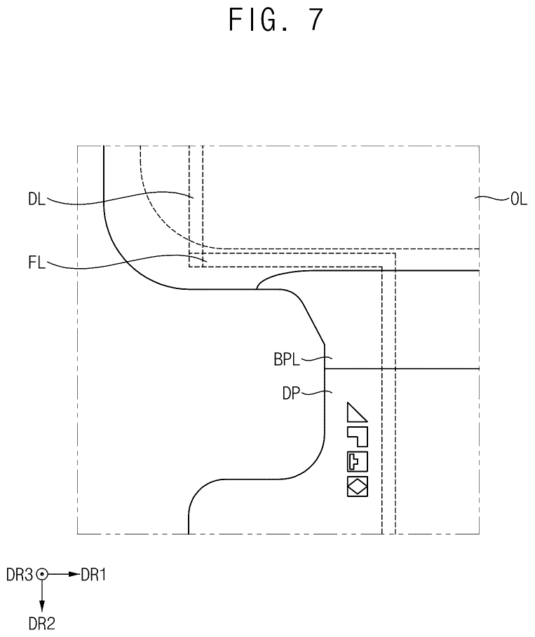

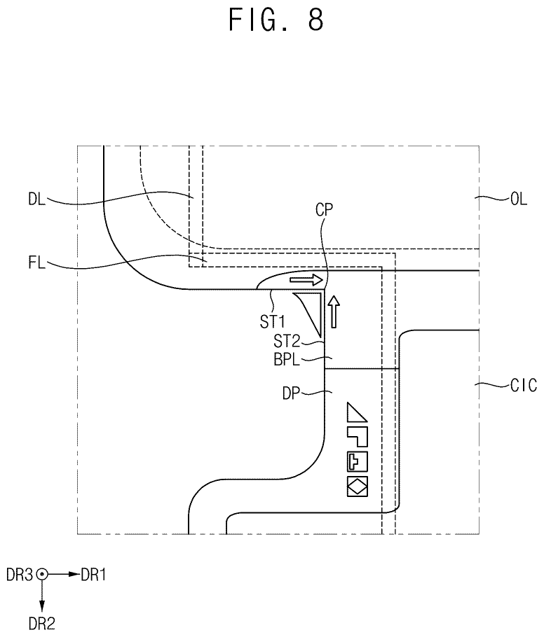

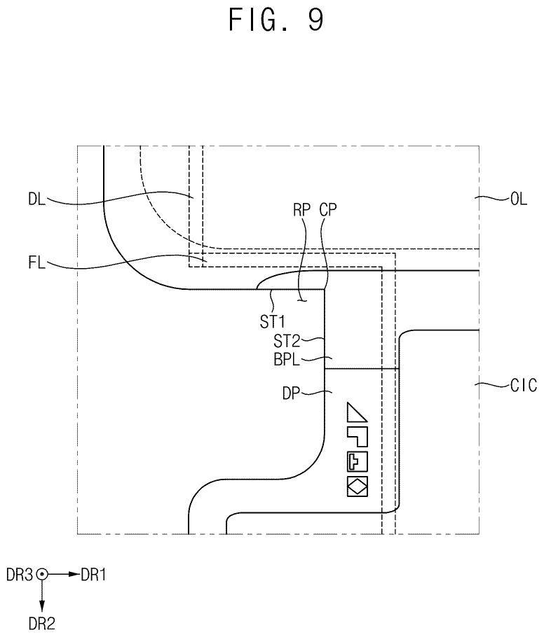

FIG. 7, FIG. 8, FIG. 9, and FIG. 10 are views illustrating a method of manufacturing the display device of FIG. 1. For example, FIG. 7, FIG. 8, FIG. 9, and FIG. 10 are views illustrating the method of manufacturing the display device DD of FIG. 1 in an area corresponding to the area A of FIG. 1.

Referring to FIG. 7, the bending protective layer BPL may be formed on the display panel DP. The bending protective layer BPL may include a first edge and a second edge extending in the first direction DR1. The first edge may be disposed to overlap the circuit board (not shown). The second edge may be disposed adjacent to the optical layer OL. The second edge may have a curved portion and a straight portion. The curved portion may meet an edge of the display panel DP.

The bending protective layer BPL may be formed on the display panel DP. An area, where the bending protective layer BPL is formed, may be a portion of the non-display area (e.g., the non-display area NDA of FIG. 1) and the bending area (e.g., the bending area BA of FIG. 1). A shape of a portion of the non-display area of FIG. 1 and edge portions of the display panel DP and bending protective layer BPL located corresponding to the bending area may not be L-shaped. For example, a first edge of the display panel DP extending in the first direction DR1 and a second edge of the display panel DP extending in the second direction DR2 may be connected by a third edge of the display panel DP disposed at an angle between the first edge and the second edge.

Referring to FIG. 8 and FIG. 9, the first straight portion ST1 of the display panel DP may be formed by irradiating a light along the first direction DR1 in the non-display area of the display panel DP. The light may penetrate the display panel DP and the bending protective layer BPL simultaneously.

The second straight portion ST2 included in the display panel DP may be formed by irradiating a light along the second direction DR2 in the non-display area of the display panel DP. The light may simultaneously penetrate the display panel DP and the bending protective layer BPL. The light may be irradiated to the display panel DP and the bending protective layer BPL along the second direction DR2 and form the intersection point CP. A portion of the display panel DP and the bending protective layer BPL may be removed by the light, and the first straight portion ST1 and the second straight portion ST2 may be formed.

That is, as illustrated in FIG. 9, after the first straight portion ST1 and the second straight portion ST2 may be formed, and a portion of each of the display panel DP and the bending protective layer BPL located outside the first straight portion ST1 and the second straight portion ST2 may be removed. For example, a portion of each of the display panel DP and the bending protective layer BPL defined by the third edge of the display panel DP may be removed. Accordingly, a recessed portion RP defined by the first straight portion ST1 and the second straight portion ST2 may be formed.

Further, a portion of the bending protective layer BPL defined by the curved portion of the bending protective layer BPL may extend opposite the direct direction DR1 and beyond the intersection point CP. For example, the portion of the bending protective layer BPL defined by the curved portion of the bending protective layer BPL may extend along the first straight portion ST1.

Referring to FIG. 10, a cutting line CUT may be formed. The cutting line CUT may be formed after the recess portion RP is formed. The cutting line CUT may be defined within the display panel DP and may be formed by irradiating a light along a direction from the intersection point CP where the first straight portion ST1 and the second straight portion ST2 intersect each other. The light may penetrate both the display panel DP and the bending protective layer BPL. In an embodiment, the direction in which the light is irradiated may be the first direction DR1. In another embodiment, the direction may be opposite to the second direction DR2. However, the direction may be varied from the intersection point CP toward the display panel DP and the bending protective layer BPL.

In an embodiment, the cutting line CUT may be formed by irradiating a light from the intersection point CP in the direction so that the cutting line CUT may not pass out the fan-out lines FL.

In an embodiment, the cutting line CUT may be formed before the recess portion RP is formed. For example, the cutting line CUT may be formed in the portion of each of the display panel DP and the bending protective layer BPL defined by the third edge of the display panel DP (see FIG. 7).

Accordingly, the display device DD of FIG. 1 may be manufactured.

In FIG. 8, FIG. 9, and FIG. 10, a process of forming the first straight portion ST1 and the second straight portion ST2 is illustrated as being performed after the cover member CIC is formed on the bending protective layer BPL, however, the present disclosure may not be limited this. For example, the first straight portion ST1 and the second straight portion ST2 may be formed before the cover member CIC is formed on the bending protective layer BPL.

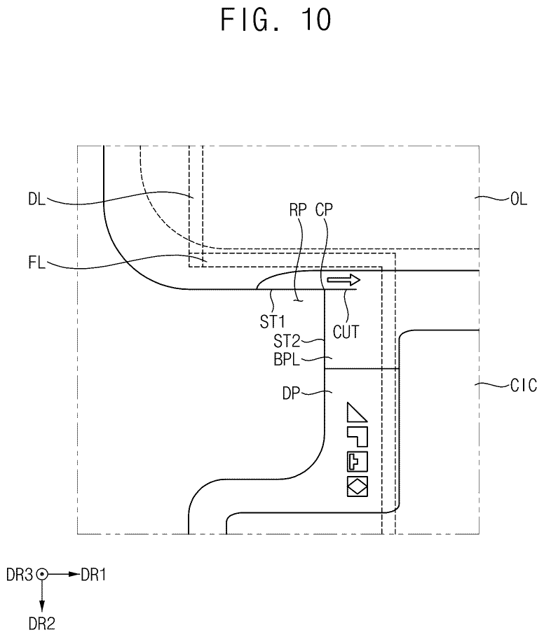

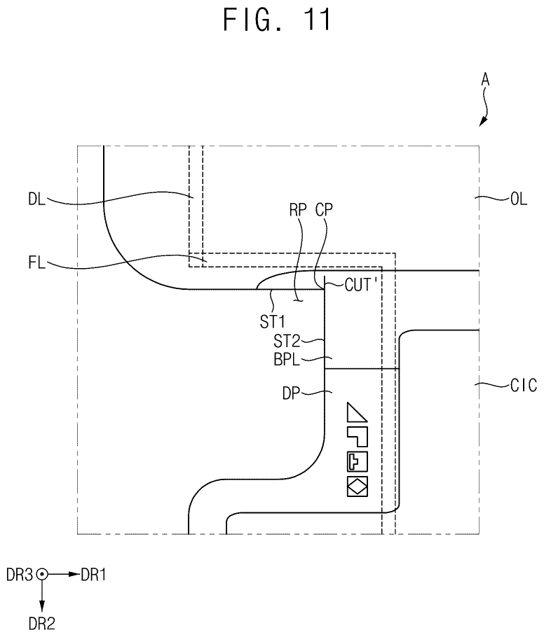

FIG. 11 is a plan view illustrating another example of an enlarged plane of the area A of FIG. 1.

The display device DD described with reference to FIG. 11 may be substantially the same as the display device DD described with reference to FIG. 6 and content that overlaps with the display device DD described with reference to FIG. 6 may be omitted or simplified.

Referring to FIG. 11, in an embodiment, a cutting line CUT′ may extend from the intersection point CP in a direction opposite to the second direction DR2. Specifically, the cutting line CUT′ may extend from the intersection point CP in a direction opposite to the second direction DR2 towards the fan-out line adjacent to the intersection point CP among the fan-out lines FL. That is, the cutting line CUT′ may be spaced apart from the fan-out lines FL in the second direction DR2.

In an embodiment, a length of the cutting line CUT′ may be less than a distance between the intersection point CP and the fan-out lines FL. Specifically, the length of the cutting line CUT′ may be less than the distance between the intersection point CP and the fan-out lines FL, and may extend in a direction opposite to the second direction DR2.

In an embodiment, a length of the cutting line CUT′ may be less than a thickness of the portion of the bending protective layer BPL in the second direction DR2 defined by the curved portion of the bending protective layer BPL extending along the first straight portion ST1. For example, the curved portion of the bending protective layer BPL may not be disconnected from a remaining portion of the bending protective layer BPL extending along the second straight portion ST2.

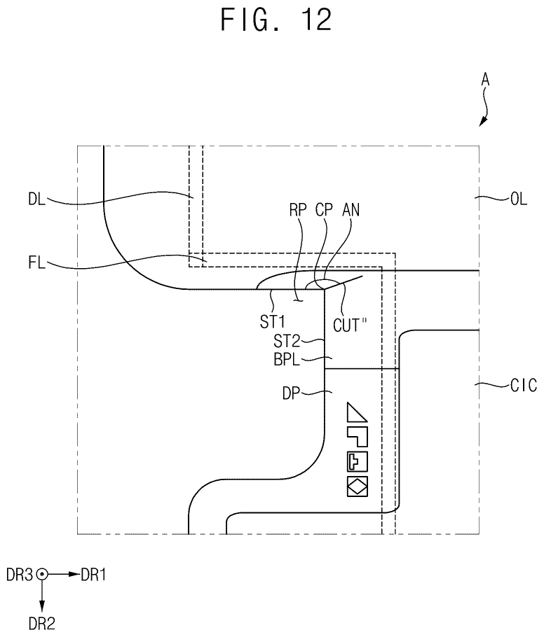

FIG. 12 is a plan view illustrating still another example of an enlarged plane of the area A of FIG. 1.

The display device DD described with reference to FIG. 12 is substantially the same as the display device DD described with reference to FIG. 6 and content that overlaps with the display device DD described with reference to FIG. 6 may be omitted or simplified.

Referring to FIG. 12, in an embodiment, a cutting line CUT″ may intersect the first straight portion ST1 at a first angle AN. The first angle AN may be more than about 0 degrees and less than about 270 degrees. For example, the cutting line CUT″ may extend between a direction opposite to the first direction DR1 and the second direction DR2 in a plan view. In addition, the first angle AN may not be about 90 degrees or about 180 degrees. In other words, the cutting line CUT″ may extend in a direction different than the first direction DR1 or the second direction DR2. In addition, the cutting line CUT″ may extend in any direction from the intersection point CP toward the display panel DP and the bending protective layer BPL.

In an embodiment, a length of the cutting line CUT″ may be less than a distance between the intersection point CP and the fan-out lines FL. Specifically, the length of the cutting line CUT″ may be less than the distance between the intersection point CP and the fan-out lines FL, and the cutting line CUT″ may extend in a direction forming the first angle AN with the first straight portion ST1.

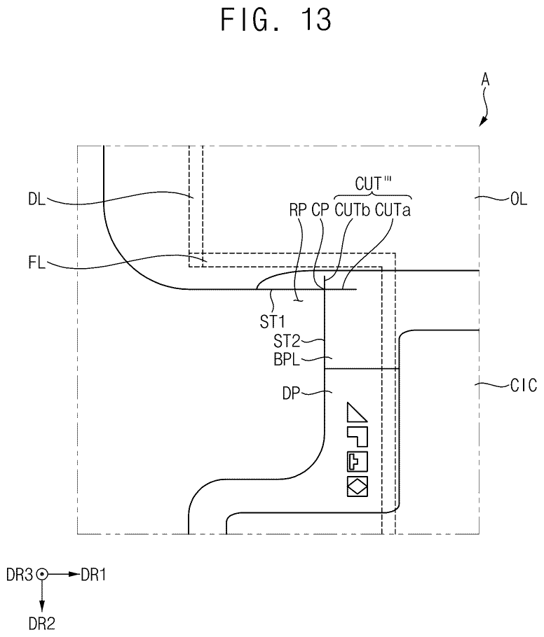

FIG. 13 is a plan view illustrating still another example of an enlarged plane of the area A of FIG. 1.

The display device DD described with reference to FIG. 13 is substantially the same as the display device DD described with reference to FIG. 6 and content that overlaps with the display device DD described with reference to FIG. 6 may be omitted or simplified.

Referring to FIG. 13, a cutting line CUT′″ may include a first cutting line CUTa and a second cutting line CUTb. Each of the first cutting line CUTa and the second cutting line CUTb may penetrate at least a portion of each of the display panel DP and the bending protective layer BPL.

In an embodiment, the first cutting line CUTa may extend from the intersection point CP in a first direction, and the second cutting line CUTb may extend from the intersection point CP in a second direction different from the first direction. In other words, directions in which the first cutting line CUTa and the second cutting line CUTb extend from the intersection point CP may be different. For example, a direction in which the first cutting line CUTa extends from the intersection point CP may be the first direction DR1, and a direction in which the second cutting line CUTb extends from the intersection point CP may be a direction opposite the second direction DR2. However, the present disclosure may not be limited to this, and directions in which the first cutting line CUTa and the second cutting line CUTb extend from the intersection point CP may be varied.

Each of the first cutting line CUTa and the second cutting line CUTb may be spaced apart from the fan-out lines FL. A length of each of the first cutting line CUTa and the second cutting line CUTb may be less than a distance between the intersection CP and the fan-out lines FL. Specifically, the length of the first cutting line CUTa extending in the first direction DR1 may be less than the distance between the intersection point CP and the fan-out lines FL in the first direction DR1. Further, the length of the second cutting line CUTb extending in a direction opposite the second direction DR2 may be less than the distance between the intersection point CP and the fan-out lines FL in the direction opposite the second direction DR2.

In an embodiment, the length of the first cutting line CUTa and the length of the second cutting line CUTb may be substantially the same. However, the present invention is not limited to this, and the length of the first cutting line CUTa and the length of the second cutting line CUTb may be different from each other.

The display device according to the embodiment may be applied to various electronic devices. An electronic device according to an embodiment of the present disclosure may include the display device (e.g., the display device DD of FIG. 1) described above, and may further include modules or devices having additional functions in addition to the display device.

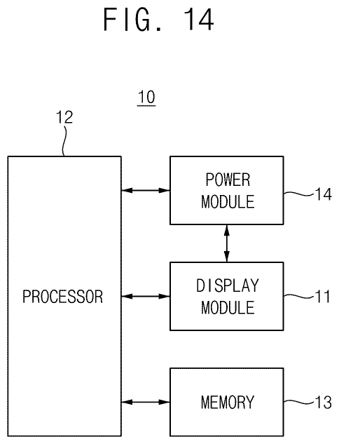

FIG. 14 is a block diagram of an electronic device according to an embodiment of the present disclosure

Referring to FIG. 14, an electronic device 10 according to an embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal may be transmitted to the display module 11, and the display module 11 may process a signal received and output image information through a display screen.

The power module 14 may include a power supply module such as a power adapter or a battery device, and a power conversion module that converts the power supplied by the power supply module to generate power necessary for the operation of the electronic device 10.

At least one of the components of the electronic device 10 described above may be included in the display device according to the embodiments described above. In addition, a part among the individual modules functionally included in one module may be included in the display device, and another part may be provided separately from the display device. For example, the display device may include the display module 11, and the processor 12, the memory 13, and the power module 14 may be provided in the form of other devices within the electronic device 10 except for the display device.

In an embodiment, the display module 11 included in the display device may drive based on the image data signal and the input control signal received from the processor 12.

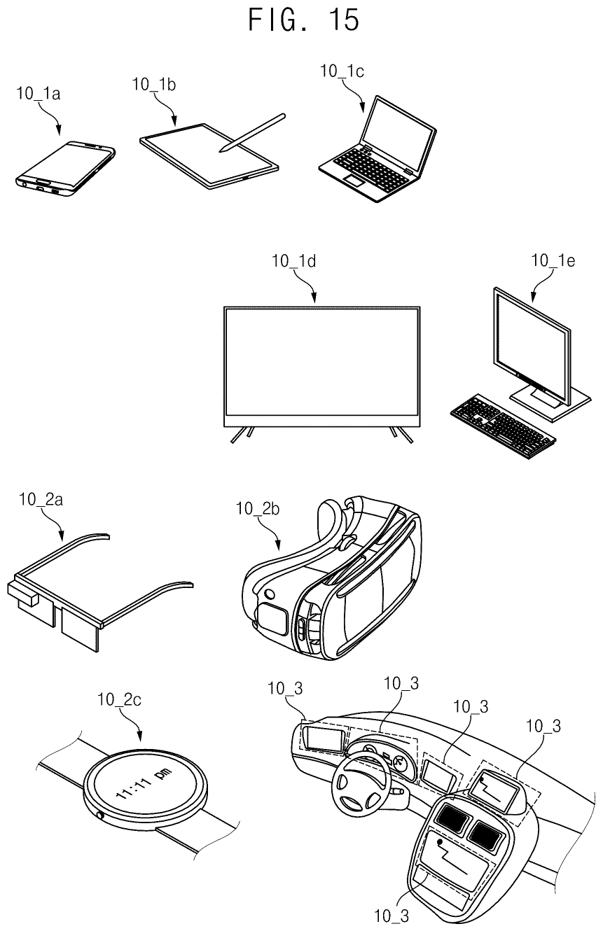

FIG. 15 is a schematic diagram of the electronic device according to various embodiments.

Referring to FIG. 15, various electronic devices to which display devices according to embodiments are applied may include not only image display electronic devices such as a smart phone 10_1a, a tablet PC 10_1b, a laptop 10_1c, a TV 10_1d, and a desk monitor 10_1e, but also a wearable electronic device including display modules such as smart glasses 10_2a, a head mounted display 10_2b, and a smart watch 10_2c, and a vehicle electronic device 10_3 including a dashboard, a center fascia, and display modules such as a CID (Center Information Display) and a room mirror display disposed in the dashboard.

The device and the method according to embodiments may be applied to an electronic device included in, for example, a computer, a notebook, a mobile phone, a smartphone, a smart pad, a PMP, a PDA, or an MP3 player.

While aspects of the invention have been particularly shown and described with reference to embodiments thereof, it will be understood by those of ordinary skill in the art that various changes in form and details may be made therein without departing from the technical spirit or scope of the invention as defined in the following claims.

What is claimed is:

1. A display device, comprising:
a display panel including a first area in which a pixel is disposed;
a second area extending in a first direction;
a third area spaced apart from the first area by the second area in a second direction perpendicular to the first direction; and
a first cutting line penetrating at least a portion of the display panel and extending from an intersection point formed by a first straight portion included in the first area and a second straight portion included in the second area.

2. The display device of claim 1, further comprising:
a fan-out line electrically connected to the pixel and extending across a boundary of the first area and the second area, and
the first cutting line is spaced apart from the fan-out line.

3. The display device of claim 1, wherein the first cutting line extends in the first direction from the intersection point.

4. The display device of claim 1, wherein the first cutting line extends in a direction opposite to the second direction from the intersection point.

5. The display device of claim 1, wherein the first cutting line extends in a third direction, which intersects with both of the first direction and the second direction in a plan view.

6. The display device of claim 1, further comprising a second cutting line penetrating at least a portion of the display panel and extending from the intersection point.

7. The display device of claim 6, wherein the display panel further includes:
fan-out lines which are electrically connected to the pixel, and extend across a boundary of the first area and the second area, and
the second cutting line is spaced apart from the fan-out lines.

8. The display device of claim 6, wherein the first cutting line and the second cutting line intersect perpendicularly at the intersection point.

9. The display device of claim 6, wherein a length of the first cutting line and a length of the second cutting line are different from each other.

10. The display device of claim 1, further comprising:
a bending protective layer overlapping at least a portion of each of the first area, the second area, and the third area,
wherein the second area is bent along a bending axis extending in a first direction.

11. The display device of claim 10, wherein the first cutting line further penetrates at least a portion of the bending protective layer.

12. The display device of claim 1, wherein the display panel defines a recess portion by the first straight portion and the second straight portion.

13. The display device of claim 12, wherein the recess portion has a L shape in a plan view.

14. The display device of claim 1, wherein the first straight portion and the second straight portion intersect perpendicularly.

15. A method of manufacturing a display device, the method comprising:
forming a bending protective layer on a display panel including a first area in which a pixel is disposed, a second area extending in a first direction, and a third area spaced apart from the first area by the second area in a second direction perpendicular to the first direction;
forming a first straight portion included in the display panel by irradiating a light in the first area along the first direction;
forming a second straight portion included in the display panel by irradiating a light in the second area along the second direction; and
forming a cutting line in the display panel by irradiating a light from an intersection point where the first straight portion and the second straight portion intersect.

16. The method of claim 15, further comprising forming a recess portion defined by the first straight portion and the second straight portion by removing a portion of each of the display panel and the bending protective layer.

17. The method of claim 16, wherein the cutting line is formed after the recess portion is formed.

18. The method of claim 15, further comprising:
providing the display panel including a fan-out line electrically connected to the pixel and extending across a boundary of the first area and the second area,
wherein in the forming of the cutting line, the light is irradiated from the intersection point toward the fan-out line for a distance less than a distance from the intersection point to the fan-out line.

19. The method of claim 15, wherein in the forming of the cutting line, the light is irradiated along the first direction from the intersection point.

20. The method of claim 15, wherein in the forming of the cutting line, the light is irradiated along a direction opposite to the second direction from the intersection point.

21. An electronic device comprising:
a processor configured to output an image data signal and an input control signal; and
a display device configured to drive based on the image data signal and the input control signal, and including:
a display panel including a first area in which a pixel is disposed;
a second area extending in a first direction;
a third area spaced apart from the first area by the second area in a second direction perpendicular to the first direction; and
a first cutting line penetrating at least a portion of the display panel and extending from an intersection point formed by a first straight portion included in the first area and a second straight portion included in the second area.
